(19) United States
(12) Patent Application Publication
(10) Pub. No.: US 2008/0075880 A1
(43) Pub. Date: Mar. 27, 2008

(54) Non-doping implantation process utilizing a plasma ion implantation system

(76) Inventors: Anthony Renau, W. Newbury, MA (US); Vikram Singh, North Andover, MA (US)

Correspondence Address: VARIAN SEMICONDUCTOR EQUIPMENT ASSC., INC., 35 DORY RD., GLOUCESTER, MA, 01930-2297, US

(21) Appl. No.: 11/527,158

(22) Filed: Sep. 26, 2006

(51) Int. Cl. C23C 14/00

(52) U.S. Cl. 427/523

(57) ABSTRACT

Non-doping implantation process utilizing a plasma ion implantation system. A plasma ion implantation system is used to perform a non-doping implantation process such as a pre-amorphization implantation process or a strain altering implantation. Use of the plasma ion implantation system to perform a non-doping implantation process results in higher throughput and is conducive to sequential ion implantation processing.

### TECHNICAL FIELD

This disclosure relates generally to plasma ion implantation of substrates, and more specifically to non-doping implantation of substrates using a plasma ion implantation system.

### BACKGROUND

Ion implantation is a standard technique for introducing conductivity-altering impurities into semiconductor wafers. In a conventional beamline ion implantation system, a desired impurity material is ionized in an ion source, the ions are accelerated to form an ion beam of prescribed energy, and the ion beam is directed at the surface of a semiconductor wafer. Energetic ions in the beam penetrate into the bulk of the semiconductor material and are embedded into the crystalline lattice of the semiconductor material to form a region of desired conductivity.

A pre-amorphization implantation is one type of non-doping ion implantation used prior to a dopant implantation in order to prevent channeling of dopant atoms. Typically, in a pre-amorphization implantation process, ions bombard the surface of the semiconductor material to perturb the crystalline lattice of the material. Ions of Germanium (Ge), Antimony (Sb), Indium (In), Silicon (Si), Argon (Ar), Fluorine (F) and Xenon (Xe) are examples of pre-amorphizing agents that can be used in a pre-amorphization implantation process because they are generally heavier molecules. In addition to perturbing the crystalline lattice of the semiconductor material, the ions are amorphizing the surface of the material. Implanting heavier molecules such as Ge in the semiconductor material and amorphizing the surface of the material will prevent channeling of dopant atoms.

Another type of non-doping ion implantation that may be performed prior to a dopant implantation is a strain altering implantation. A strain altering implantation perturbs the crystalline lattice with a greater dose of ions, which after the proper anneal, stresses, stretches or strains the lattice so that electrons can flow with less resistance. A strained crystalline lattice is generally beneficial in improving drive current in transistors which enables them to run faster.

Typically, a conventional beamline ion implantation system is used to perform non-doping implantations such as a pre-amorphization implantation and a strain altering implantation. In a conventional beamline ion implantation system, a stream of ions are extracted from an ion source, manipulated and focused into a beam which is rastered onto a target wafer. For example, an ion source generates an ion beam and extraction electrodes extract the beam from the source. An analyzer magnet receives the ion beam after extraction and filters selected ion species from the beam. The ion beam passing through the analyzer magnet then enters an electrostatic lens comprising multiple electrodes with defined apertures that allow the ion beam to pass through. By applying different combinations of voltage potentials to the multiple electrodes, the electrostatic lens can manipulate ion energies. A corrector magnet shapes the ion beam generated from the electrostatic lens into the correct form for deposition onto the wafer. A deceleration stage that comprises a deceleration lens receives the ion beam from the corrector magnet and further manipulates the energy of the ion beam before it hits the wafer causing the ions come to rest beneath the surface.

A drawback associated with using a conventional beamline ion implantation system for performing non-doping implantations such as a pre-amorphization implantation and a strain altering implantation is that there are limits on the throughput. In addition, the use of a conventional beamline ion implantation system for performing a pre-amorphization implantation or a strain altering implantation is not conducive to performing subsequent ion implantations with other tools. For example, if one wanted to use a plasma doping system to perform an additional ion implantation subsequent to the pre-amorphization implantation or the strain altering implantation, the vacuum would have to be broken and the wafer removed from the process chamber of the conventional beamline ion implantation system and placed in the plasma doping system. Therefore, it is desirable to have an ion implantation system that can perform non-doping implantations with high throughput and that is conducive to sequential ion implantation processing.

### SUMMARY

In one embodiment, there is a method for plasma ion implantation of a substrate. In this embodiment, a plasma ion implantation system is provided that includes a process chamber, a source for supplying a process gas into the process chamber, a platen for holding the substrate in the process chamber, a radio frequency energy source for generating plasma in the process chamber and a voltage source for accelerating ions from the plasma into the substrate. A non-doping implantation is performed on the substrate with the plasma ion implantation system according to a first implant process having a dose rate.

In a second embodiment, there is a method for plasma ion implantation of a substrate. In this embodiment, a plasma ion implantation system is provided that includes a process chamber, a source for supplying a process gas into the process chamber, a platen for holding the substrate in the process chamber, a radio frequency energy source for generating plasma in the process chamber and a voltage source for accelerating ions from the plasma into the substrate. A non-doping implantation is performed on the substrate with the plasma ion implantation system according to a first implant process having a dose rate. A plasma ion implantation is then performed on the non-doped implanted substrate with the plasma ion implantation system according to a second implant process having a dose rate.

In a third embodiment, there is a method for plasma ion implantation of a substrate. In this embodiment, a plasma ion implantation system is provided that includes a process chamber, a source for supplying a process gas into the process chamber, a platen for holding the substrate in the process chamber, a radio frequency energy source for generating plasma in the process chamber and a voltage source for accelerating ions from the plasma into the substrate. A non-doping implantation is performed on the substrate with the plasma ion implantation system according to a first implant process having a dose rate. The non-doping implantation of the substrate comprises at least one of the following: a pre-amorphization implantation or a strain altering implantation. A plasma ion implantation is sequentially performed on the non-doped implanted substrate with the plasma ion implantation system according to a second implant process having a dose rate.

### BRIEF DESCRIPTION OF THE DRAWINGS

FIG. 1 shows a simplified schematic of a plasma ion implantation system according to one embodiment of the disclosure; and

FIG. 2 shows a flow chart describing a method for performing a non-doping implant and subsequent ion implants with the plasma ion implantation system shown in FIG. 1.

### DETAILED DESCRIPTION

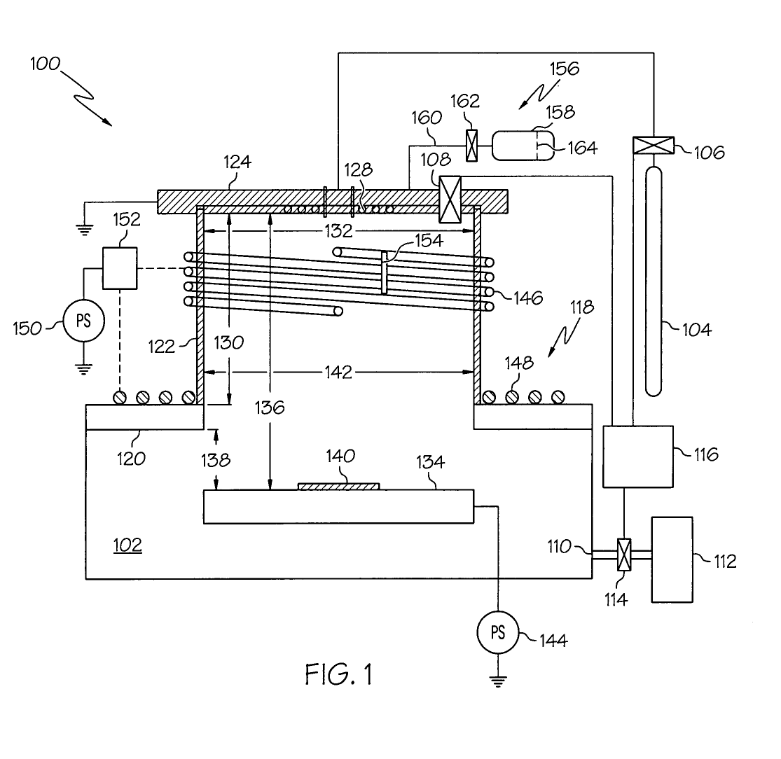

FIG. 1 shows a simplified schematic of a plasma ion implantation system according to one embodiment of the disclosure. In particular, FIG. 1 shows a plasma immersion ion implantation system 100. Although the plasma ion implantation system described in this disclosure relates to a plasma immersion ion implantation system, the scope of this disclosure is applicable to other plasma ion implantation systems. Referring back to FIG. 1, plasma ion implantation system 100 comprises a plasma process chamber 102 that defines an enclosed volume. A gas source 104, coupled to a plasma process chamber 102 through a proportional valve 106, supplies a process gas to the chamber. A pressure gauge 108 measures the pressure inside the chamber 102. A vacuum pump 112 evacuates exhausts from the plasma process chamber 102 through an exhaust port 110 in the chamber. An exhaust valve 114 controls the exhaust conductance through the exhaust port 110.

The plasma immersion ion implantation system 100 further includes a gas pressure controller 116 that is electrically connected to the proportional valve 106, the pressure gauge 108, and the exhaust valve 114. The gas pressure controller 116 maintains the desired pressure in the plasma process chamber 102 by controlling the exhaust conductance with the exhaust valve 114 and controlling the process gas flow rate with the proportional valve 106 in a feedback loop that is responsive to the pressure gauge 108.

FIG. 1 shows that the plasma process chamber 102 has a chamber top 118 that includes a first section 120 formed of a dielectric material that extends in a generally horizontal direction. A second section 122 of the chamber top 118 is formed of a dielectric material that extends at a height from the first section 120 in a generally vertical direction. The dimensions of the first and the second sections 120, 122 of the chamber top 118 can be selected to improve the uniformity of plasma generated in the chamber 102.

The dielectric materials in the first and second sections 120, 122 provide a medium for transferring RF power from a RF antenna 146, 148 to plasma that forms inside the chamber 102. In one embodiment, the dielectric material used to form the first and second sections 120, 122 is a high purity ceramic material that is chemically resistant to the process gases and that has good thermal properties. For example, in some embodiments, the dielectric material is 99.6% aluminum oxide (Al₂O₃) or aluminum nitride (AlN). In other embodiments, the dielectric material is yttrium (Y) and yttrium aluminum garnet (YAG).

The chamber top 118 as shown in FIG. 1 further includes a top section 124 formed of a conductive material that extends a length across the second section 122 in the horizontal direction. In one embodiment, the conductive material used to form the top section 124 is aluminum. Also, in another embodiment, the conductivity of the material used to form the top section 124 is high enough to dissipate the heat load and to minimize charging effects that results from secondary electron emission. Typically, the conductive material used to form the top section 124 is chemically resistant to the process gases.

The top section 124 can be coupled to the second section 122 with a halogen resistant 0-ring made of fluorocarbon polymer, such as an O-ring formed of CHEMRAZ and/or KALREZ materials. The top section 124 is typically mounted to the second section 122 in a manner that minimizes compression on the second section 122, but that provides enough compression to seal the top section 124 to the second section. In some operating modes, the top section 124 is RF and DC grounded as shown in FIG. 1.

In one embodiment, the top section 124 comprises a cooling system that regulates the temperature of the top section 124 in order to further dissipate the heat load generated during processing. As shown in FIG. 1, the cooling system can be a fluid cooling system that includes cooling passages 128 in the top section 124 that circulate a liquid coolant from a coolant source. The liquid coolant is helpful in reducing thermal stress points that can form during a plasma doping process and eventually lead to chamber failure.

In one embodiment, a ratio of the height 130 of the first section 122 of the chamber top 118 in the vertical direction to the length 132 across the second section 122 of the chamber top 118 in the horizontal direction is approximately between 1.5 and 5.5. In the embodiment shown in FIG. 1, the second section 122 is formed in a cylindrical shape. However, in another embodiment, the first section 120 of the chamber top 118 does not have to extend in exactly a horizontal direction. Also, in another embodiment, the second section 122 of the chamber top 118 does not have to extend in exactly a vertical direction.

The plasma immersion ion implantation system 100 shown in FIG. 1 further includes a platen 134 positioned in the plasma process chamber 102 at a height 136 below the top section 124 of the chamber top 118 and at a height 138 below the first section 120 of the chamber top 118. The platen 134 can be a substrate holder that holds a substrate 140 such as a semiconductor wafer for ion implantation.

A bias voltage power supply 144 is electrically connected to the platen 134. The bias voltage power supply 144 biases the platen 134 at a voltage that attracts ions in the plasma to the wafer 140. The bias voltage power supply 144 can be a DC power supply or a RF power supply.

Although not shown in FIG. 1, there are one or more Faraday cups positioned adjacent to the platen 134 for measuring the ion dose implanted into the wafer 140. Typically, Faraday cups are equally spaced around the periphery of the wafer. Each Faraday cup comprises a conductive enclosure having an entrance facing the plasma. Each Faraday cup is preferably positioned as close as is practical to the wafer and intercepts a sample of the positive ions accelerated from the plasma toward the platen.

The Faraday cups are generally electrically connected to a dose processor or other dose monitoring circuit (not shown). Positive ions entering each Faraday cup through the entrance produce in the electrical circuit connected to the Faraday cup a current that is representative of ion current. The dose processor may process the electrical current to determine ion dose.

Another element not shown in the plasma immersion ion implantation system 100 of FIG. 1 is a guard ring that surrounds the platen 134. The guard ring may be biased to improve the uniformity of implanted ion distribution near the edge of the wafer 140. The Faraday cups may be positioned within the guard ring near the periphery of the wafer 140 and the platen 134.

FIG. 1 shows that the plasma immersion ion implantation system 100 comprises a RF antenna positioned proximate to at least one of the first section 120 and the second section 122 of the chamber top 118. As shown in FIG. 1, there are two separate RF antennas that are electrically isolated. A planar coil antenna 148 having a plurality of turns is positioned adjacent to the first section 120 of the chamber top 118 and a helical coil antenna 146 having a plurality of turns surrounds the second section 122 of the chamber top 118.

A RF source 150, such as a RF power supply, is electrically connected to at least one of the planar coil antenna 146 and the helical coil antenna 148. The RF source 150 is coupled to the RF antennas 146, 148 by an impedance matching network 152 that maximizes the power transferred from the RF source 150 to the RF antennas 146, 148. Dashed lines from the output of the impedance matching network 152 to the planar coil antenna 146 and the helical coil antenna 148 are used to indicate that electrical connections can be made from the output of the impedance matching network 152 to either or both of the planar coil antenna 146 and the helical coil antenna 148

The RF source 150 resonates RF currents in the RF antennas 146, 148. The RF current in the RF antennas 146, 148 induces RF currents into the plasma process chamber 102. The RF currents in the plasma process chamber 102 excite and ionize the process gas so as to generate a plasma in the chamber.

One of ordinary skill in the art will recognize that the plasma immersion ion implantation system 100 may have many different antenna configurations. In one embodiment, at least one of the planar coil antenna 146 and the helical coil antenna 148 is an active antenna. The term “active antenna” is an antenna that is driven directly by a power supply. In other words, a voltage generated by the power supply is directly applied to an active antenna.

In another embodiment, at least one of the planar coil antenna 146 and the helical coil antenna 148 can be liquid cooled. For example, the planar coil antenna 146 and the helical coil antenna 148 can be tubular members that are connected to a pressurized fluid source. Cooling at least one of the planar coil antenna 146 and the helical coil antenna 148 will reduce temperature gradients caused by the RF power propagating in the RF antennas 146, 148.

In another embodiment, one of the planar coil antenna 146 and the helical coil antenna 148 is a parasitic antenna. The term “parasitic antenna” is an antenna that is in electromagnetic communication with an active antenna, but that is not directly connected to a power supply. In other words, a parasitic antenna is not directly excited by a power supply, but rather is excited by an active antenna.

For example, in one embodiment, the planar coil antenna 146 is an active antenna that is electrically connected to the output of the power supply 150 and the helical coil antenna 148 is a parasitic antenna that is positioned in electromagnetic communication with the planar coil antenna 146. In another embodiment, the helical coil antenna 148 is an active antenna that is electrically connected to the output of the power supply 150 and the planar coil antenna 146 is positioned in electromagnetic communication with the helical coil antenna 148.

In another embodiment, one end of the parasitic antenna is electrically connected to ground potential in order to provide antenna tuning capabilities. In this embodiment, the parasitic antenna includes a coil adjuster that is used to change the effective number of turns in the parasitic antenna coil. Numerous different types of coil adjusters can be used. For example, the coil adjuster 154 shown in FIG. 1 is a metal short that is positioned between a floating end of the parasitic coil and a desired number of turns in the helical coil antenna 148. In one embodiment, the parasitic antenna is electrically floating at both ends. In this embodiment, a switch (not shown) is used to select the desired number of turns in the parasitic antenna coil.

FIG. 1 shows that the plasma immersion ion implantation system 100 further includes a plasma igniter 156. Numerous types of plasma igniters can be used with the plasma immersion ion implantation system 100. In one embodiment, the plasma igniter 156 includes a reservoir 158 of strike gas, which is a highly-ionizable gas, such as argon (Ar), that assists in igniting the plasma. The reservoir 158 can be a relatively small reservoir of known volume and known pressure. The reservoir 158 is coupled to the plasma process chamber 102 with a high conductance gas connection 160. A burst valve 162 isolates the reservoir 158 from the chamber 102. In another embodiment, a strike gas source is plumbed directly to the burst valve 162 using a low conductance gas connection.

In operation, the plasma process chamber 102 is evacuated to high vacuum. The process gas is then introduced into the plasma process chamber 102 by the proportional valve 106 and exhausted from the chamber by the vacuum pump 112. The gas pressure controller 116 is used to maintain the desired gas pressure for a desired process gas flow rate and exhaust conductance.

The RF source 150 generates a RF signal that is applied to the RF antennas 146, 148. In one embodiment, the RF source 150 generates a relatively low frequency RF signal. Using a relatively low frequency RF signal will minimize capacitive coupling and, therefore will reduce sputtering of the chamber walls and the resulting contamination. For example, in this embodiment, the RF source 150 generates RF signals below 27 MHz, such as 400 kHz, 2 MHz, 4 MHz or 13.56 MHz.

The RF signal applied to the RF antennas 146, 148 generates a RF current in the RF antennas 146, 148. Electromagnetic fields induced by the RF currents in the RF antennas 146, 148 couple through at least one of the dielectric material forming the first section 120 and the dielectric material forming the second section 122 and into the plasma process chamber 102. In some operating modes, RF current is induced through the first section 120 of the chamber top 118 with an active antenna that is electrically coupled to the RF source 150 and through the second section 122 of the chamber top 118 with a parasitic antenna. In other operating modes, RF current is induced through the second section 122 of the chamber top 118 with an active antenna that is electrically coupled to the RF source 150 and through the first section 120 of the chamber top 118 with a parasitic antenna.

The electromagnetic fields induced in the plasma process chamber 102 excite and ionize the process gas molecules. Plasma ignition occurs when a small number of free electrons move in such a way that they ionize some process gas molecules. The ionized process gas molecules release more free electrons that ionize more gas molecules. This ionization process continues until a steady state of ionized gas and free electrons are present in the plasma. In one embodiment, the characteristics of the plasma are tuned by changing the effective number of turns in the parasitic antenna coil with the coil adjuster 154. Implanting of the target wafer 140 is then conducted using the ionic plasma by providing a negative voltage to the target.

Additional details of a plasma immersion ion implantation system are provided in US Patent Application Publication Number 2005/0205212.

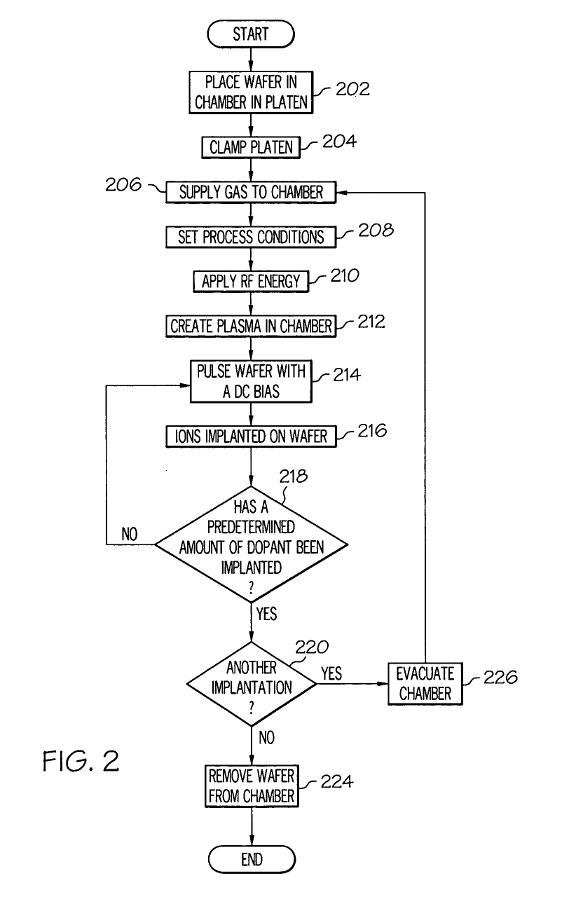

FIG. 2 shows a flow chart 200 describing a method for performing a non-doping implant and subsequent ion implants with the plasma immersion ion implantation system 100 shown in FIG. 1. The method begins at 202 where a wafer is placed in the process chamber and positioned on the platen. The platen is clamped at 204, gas is supplied into the process chamber at 206 and process conditions are set at 208. In one embodiment, for a pre-amorphization implant, the gas that enters the process chamber may be selected from the group consisting of Germanium (Ge), Antimony (Sb), Indium (In), Silicon (Si), Argon (Ar), Fluorine (F) and Xenon (Xe). The preferred gas for performing the pre-amorphization implant is Ge because it is a heavy molecule that has better results from a kinetics point of view. That is, Ge induces greater disorder in the crystal material of the semiconductor material and requires a lower implant dose to attain amorphization. The gas may enter the process chamber at a gas flow rate that ranges from about 1 standard cubic centimeter (sccm) to about 3000 sccm and has a pressure that ranges from 0.05 millitorr (mT) to about 500 mT.

In another embodiment, for a strain altering implant, Ge is the gas that is typically supplied to the process chamber. For this embodiment, the gas may enter the process chamber at a gas flow rate that ranges from about 1 sccm to about 3000 sccm and has a pressure that ranges from 0.05 millitorr to about 500 millitorr.

Referring back to FIG. 2, the RF energy source generates RF energy at 210. In particular, the RF source resonates RF currents in the antennas which induce electromagnetic fields within the plasma process chamber. The electromagnetic fields induced in the plasma process chamber excite and ionize process gas molecules. Plasma is created in the chamber at 212 when a small number of gas molecules move in such a way that they ionize some of the process gas molecules. The ionized process gas molecules release more free electrons that ionize more gas molecules. Eventually, this ionized process results in a steady state of ionized gas and free electrons that are present in plasma. To generate plasma in the plasma process chamber the RF energy source preferably operates with a voltage that is in the range from about 0.1 keV to about 10 keV.

The wafer is pulsed with a negative DC bias at 214. In one embodiment, the DC bias that is pulsed to the wafer has a voltage that ranges from about 10 volts to about 20,000 volts in amplitude. Generally, the DC bias that is selected is a function of the desired depth for the ion implantation. The number of pulses and the pulse duration of the DC bias are selected to provide a desired dose of impurity material in the substrate. The current per pulse is a function of pulse voltage, gas pressure and species and any variable position of the electrodes. In one embodiment, the pulse duration of the DC bias for performing the non-doping implant is from about 1 μs to about 1 ms, while the pulse repetition rate is from about 0.1 kHz to about 20 kHz. These parameter values are illustrative only of possible values and one of ordinary skill in the art will recognize that other values may be selected. Applying the DC bias will create an electric field that accelerates the positive ions from the plasma across the plasma sheath toward the platen. The accelerated ions are subsequently implanted into the wafer at 216 to form regions of impurity material.

At 218 a determination is made with regard to the amount of dopant implanted into the substrate. If the Faraday cups determine that the specified amount of ions have not been implanted into the substrate then the implantation continues. In particular, process acts 214-216 continue until enough ions have been implanted in the substrate. Once enough ions have been implanted, then another decision is made at 220. In particular, a decision is made regarding whether one wants to perform another ion implant using the plasma ion implantation system. If no more implants are desired, then the wafer is removed from the plasma process chamber at 224 and later cut into individual integrated circuits after subsequent processing. Alternatively, if another implant such as an n or p dopant implant is desired, then the process chamber is evacuated at 226 and another implant process at a specified dopant rate is initiated and process acts 206-220 are repeated at process conditions that are in accordance with the n or p dopant implant.

The foregoing flow chart shows some of the processing functions associated with using the plasma immersion ion implantation system to perform a non-doping implant such as a pre-amorphization implant and a strain altering implant, as well as additional dopant implants. In this regard, each block represents a process act associated with performing these functions. It should also be noted that in some alternative implementations, the acts noted in the blocks may occur out of the order noted in the figure or, for example, may in fact be executed substantially concurrently or in the reverse order, depending upon the act involved. Also, one of ordinary skill in the art will recognize that additional blocks that describe the processing functions may be added.

It is apparent that there has been provided with this disclosure a non-doping implantation process utilizing a plasma ion implantation system. While the disclosure has been particularly shown and described in conjunction with a preferred embodiment thereof, it will be appreciated that variations and modifications can be effected by a person of ordinary skill in the art without departing from the scope of the disclosure.

What is claimed is:

1. A method for plasma ion implantation of a substrate, comprising:
providing a plasma ion implantation system including a process chamber, a source for supplying a process gas into the process chamber, a platen for holding the substrate in the process chamber, a radio frequency energy source for generating plasma in the process chamber and a voltage source for accelerating ions from the plasma into the substrate; and
performing a non-doping implantation of the substrate with the plasma ion implantation system according to a first implant process having a dose rate.

2. The method of claim 1, wherein the performing of the non-doping implantation of the substrate comprises at least one of the following: a pre-amorphization implantation or a strain altering implantation.

3. The method of claim 2, wherein the pre-amorphization implantation of the substrate comprises using ions selected from the group consisting of Germanium (Ge), Antimony (Sb), Indium (In), Silicon (Si), Argon (Ar), Fluorine (F) and Xenon (Xe).

4. The method of claim 1, further comprising performing a plasma ion implantation on the non-doped implanted substrate with the plasma ion implantation system according to a second implant process having a dose rate.

5. The method of claim 4, wherein the plasma ion implantation is performed sequentially to the non-doping implantation.

6. The method of claim 4, wherein the plasma ion implantation is a doping implant.

7. A method for plasma ion implantation of a substrate, comprising:
providing a plasma ion implantation system including a process chamber, a source for supplying a process gas into the process chamber, a platen for holding the substrate in the process chamber, a radio frequency energy source for generating plasma in the process chamber and a voltage source for accelerating ions from the plasma into the substrate;
performing a non-doping implantation of the substrate with the plasma ion implantation system according to a first implant process having a dose rate; and
performing a plasma ion implantation on the non-doped implanted substrate with the plasma ion implantation system according to a second implant process having a dose rate.

8. The method of claim 7, wherein the performing of the non-doping implantation of the substrate comprises at least one of the following: a pre-amorphization implantation or a strain altering implantation.

9. The method of claim 8, wherein the pre-amorphization implantation of the substrate comprises using ions selected from the group consisting of Germanium (Ge), Antimony (Sb), Indium (In), Silicon (Si), Argon (Ar), Fluorine (F) and Xenon (Xe).

10. The method of claim 7, wherein the plasma ion implantation is performed sequentially to the non-doping implantation.

11. The method of claim 7, wherein the plasma ion implantation is a doping implant.

12. A method for plasma ion implantation of a substrate, comprising:
providing a plasma ion implantation system including a process chamber, a source for supplying a process gas into the process chamber, a platen for holding the substrate in the process chamber, a radio frequency energy source for generating plasma in the process chamber and a voltage source for accelerating ions from the plasma into the substrate;
performing a non-doping implantation of the substrate with the plasma ion implantation system according to a first implant process having a dose rate, wherein the non-doping implantation of the substrate comprises at least one of the following: a pre-amorphization implantation or a strain altering implantation; and
sequentially performing a plasma ion implantation on the non-doped implanted substrate with the plasma ion implantation system according to a second implant process having a dose rate.

13. The method of claim 12, wherein the pre-amorphization implantation of the substrate comprises using ions selected from the group consisting of Germanium (Ge), Antimony (Sb), Indium (In), Silicon (Si), Argon (Ar), Fluorine (F) and Xenon (Xe).

14. The method of claim 12, wherein the plasma ion implantation is a doping implant.
